(19) United States
(12) Patent Application Publication
(10) Pub. No.: US 2026/0247669 A1
(43) Pub. Date: Aug. 20, 2026

(54) BURIED P+ EPITAXIAL LAYERS FOR ROBUST ISOLATION IN HIGH-VOLTAGE BIPOLAR-CMOS-DMOS DEVICES

(71) Applicant: Taiwan Semiconductor Manufacturing Company, Ltd., Hsinchu (TW)

(72) Inventors: Yu-Hung Cheng, Tainan (TW); Liang-Yu Su, Yunlin County (TW); Kuan-Liang Liu, Pingtung County (TW); Ching I Li, Tainan (TW)

(21) Appl. No.: 19/057,877

(22) Filed: Feb. 19, 2025

(51) Int. Cl. H10D 62/10; H10D 62/00

(52) U.S. Cl. CPC H10D 62/112; H10D 62/01

(57) ABSTRACT

Techniques are described for robust transistor isolation in high-voltage Bipolar-CMOS-DMOS (HV-BCD) devices. Embodiments incorporate silicon-boron (Si:B) epitaxially grown (EPI) buried layers into HV-BCD devices, such between a P-substrate and a P-EPI layer. Such structures reduce parasitic NPN transistor effects by controlling the alpha ratio, linked to boron concentration and electron diffusion barriers. Some embodiments add co-doped layers with oxygen and/or carbon to control P-EPI layer features, such as thickness, dopant profile, and breakdown voltage (Vbd). Co-doping can be achieved by low-pressure chemical vapor deposition (LPCVD).

### TECHNICAL FIELD

The present disclosure relates to semiconductor devices and, more particularly, to electrical isolation for high-voltage bipolar-CMOS-DMOS (HV-BCD) devices.

### BACKGROUND

Bipolar-CMOS-DMOS (BCD) devices integrate bipolar, complementary metal-oxide-semiconductor (CMOS), and double-diffused metal-oxide-semiconductor (DMOS) transistors on a single chip. BCD devices are used in many contexts, such as power management and automotive electronics. Ensuring robust isolation between different device regions in such devices is critical to maintaining their reliable operation, particularly under high-voltage (HV) conditions.

### BRIEF DESCRIPTION OF THE DRAWINGS

The present disclosure is best understood from the following detailed description when read with the accompanying figures. It is noted that, in accordance with the standard practice in the industry, various features are not drawn to scale and are used for illustration purposes only. In fact, the dimensions of the various features may be arbitrarily increased or reduced for clarity.

FIG. 1 shows a lateral double-diffused metal-oxide-semiconductor (DMOS) transistor with deep trench isolation (DTI) structures designed to mitigate the parasitic NPN transistor effect, thereby reducing leakage currents, according to some conventional approaches.

FIG. 2 shows a plot illustrating the parasitic NPN transistor effect and its behavior in context of different conventional process technologies.

FIGS. 3A and 3B show an example of a lateral DMOS transistor with both DTI and a P+ substrate, and a lateral DMOS transistor with DTI and SOI technology, respectively.

FIG. 4 shows an illustrated high-voltage bipolar-CMOS-DMOS (HV-BCD) device structure including a buried P+ EPI layer, according to some embodiments described herein.

FIG. 5 shows an illustrated HV-BCD device structure that is similar to the HV-BCD device structure of FIG. 4 with additional one or more co-doped layers, according to some embodiments described herein.

FIG. 6A-6C show three illustrative partial structures representing examples of co-doped layer(s) of the P+ EPI layer, according to some embodiments described herein.

FIG. 7 shows a secondary ion mass spectrometry (SIMS) profile plot to demonstrate that an oxygen-doped layer reduces boron diffusion.

FIG. 8 shows a flow diagram of a method for producing electrical isolation between HV-BCD devices, according to embodiments described herein.

### DETAILED DESCRIPTION

The present disclosure provides many different embodiments, or examples, for implementing different features of the provided subject matter. Embodiments disclosed herein are merely examples and are not intended to be limiting. For example, dimensions of elements are for illustration only and should not be construed to limit ranges or values of those dimensions in accordance with the disclosure. Specific examples of components and arrangements are described below to simplify the present disclosure. These are, of course, merely examples and are not intended to be limiting. The present disclosure may repeat reference numerals and/or letters in the various examples. This repetition is for the purpose of simplicity and clarity and does not in itself dictate a relationship between the various embodiments and/or configurations discussed.

Spatially relative terms, such as “beneath,” “below,” “lower,” “above,” “upper,” “top,” “bottom” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The device may be otherwise oriented (rotated 90 degrees or at other orientations) and the spatially relative descriptors used herein may likewise be interpreted accordingly. The term “horizontal” is defined as a plane parallel to the conventional plane or main surface of a wafer or substrate, regardless of the orientation of the wafer or substrate. The term “vertical” refers to a direction perpendicular to the horizontal as defined above. It will be understood that, although the terms “first,” “second,” “third,” etc. may be used herein to describe various elements, components, regions, layers and/or sections, these elements, components, regions, layers and/or sections should not be limited by these terms. These terms are only used to distinguish one element, component, region, layer or section from another region, layer or section. Thus, a first element, component, region, layer or section discussed below could be termed a second element, component, region, layer or section without departing from the teachings of the present disclosure.

Bipolar-CMOS-DMOS (BCD) devices integrate bipolar, complementary metal-oxide-semiconductor (CMOS), and double-diffused metal-oxide-semiconductor (DMOS) transistors on a single chip. BCD devices are used in many contexts, such as power management and automotive electronics. Ensuring robust isolation between different device regions in such devices is critical to maintaining their reliable operation, particularly under high-voltage (HV) conditions. The description herein relates to challenges encountered in isolating HV-BCD devices, which tend to be plagued by leakage currents and parasitic effects that can severely degrade their performance.

Minimizing leakage currents and ensuring reliable high-voltage operation (e.g., for devices operating at 120V) can rely on achieving effective isolation. In particular, HV-BCD devices often experience significant leakage currents due to parasitic NPN transistor effects and electron injection from the substrate. These leakage currents can compromise the performance and reliability of the devices. Conventional approaches to addressing such concerns tend to be costly and deficient. For example, some conventional approaches use a P+ substrate or Silicon-On-Insulator (SOI) technology, both of which tend to be too expensive for many applications. Additionally, some conventional approaches struggle to provide enough control over boron diffusion and electron leakage to achieve desired levels of isolation performance. Embodiments described herein seek to provide cost-effective approaches to achieve robust isolation for HV-BCD devices.

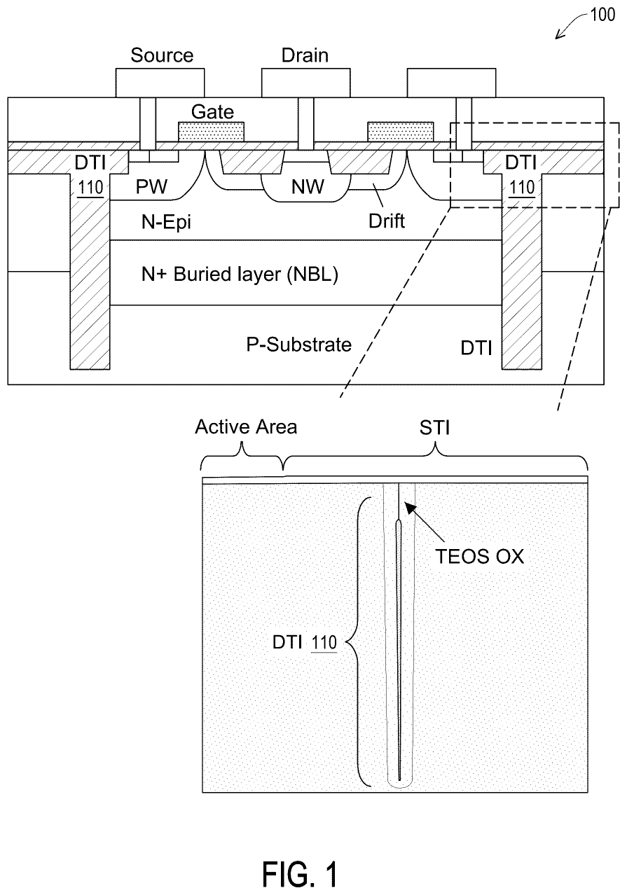

For added context, FIG. 1 shows a lateral double-diffused metal-oxide-semiconductor (DMOS) transistor 100 with deep trench isolation (DTI) structures 110 designed to mitigate the parasitic NPN transistor effect, thereby reducing leakage currents. As illustrated, the DTI structures 110 are incorporated into the DMOS transistor 100 to create physical barriers that prevent unintended current paths. Physically blocking the leakage current path is one conventional approach to mitigating leakage in high-voltage operations. However, such an approach has certain limitations. For example, such approaches can tend to provide incomplete leakage reduction. For example, while the DTI structures 110 can reducing leakage currents caused by the parasitic NPN transistor effect, they may not entirely eliminate all unintended current paths. Another limitation is that use of DTI structures 110 alone can have limited effectiveness for dealing with high-voltage requirements. As the voltage increases, the effectiveness of DTI structures 110 in preventing leakage currents may diminish, leading to potential reliability issues in HV-BCD devices.

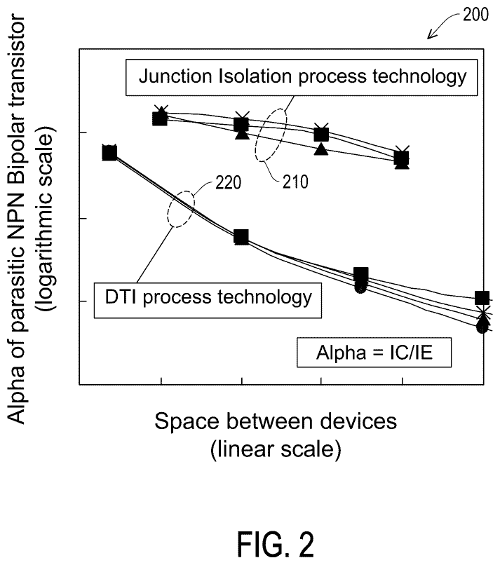

FIG. 2 shows a plot 200 illustrating the parasitic NPN transistor effect and its behavior in context of different types of process technologies. As noted above, according to the parasitic NPN transistor effect, unintended leakage paths are formed, increasing leakage currents and undermining the isolation performance of BCD devices. A first data group 210 (including a first related set of data series) represents leakage current paths that occur when using traditional junction isolation technology alone. Junction isolation uses P-N junctions to isolate different regions of the device. However, this technology is prone to forming unintended current paths due to the parasitic NPN transistors that can develop within the structure. These parasitic transistors can lead to significant leakage currents, which degrade the isolation performance and reliability of the device.

A second data group 220 (including a second related set of data series) represents the leakage current paths when DTI process technology is incorporated into the device. As shown in FIG. 1, DTI involves etching deep trenches into the silicon substrate and filling them with an insulating material, such as oxide, to create a physical barrier that prevents the formation of unintended current paths. By incorporating DTI, the parasitic NPN transistor effect is significantly reduced. In fact, the second data group 220 demonstrates a third-order Alpha reduction. The Alpha ratio is a parameter that measures the isolation performance, defined as the ratio of the collector current to the base current in a parasitic NPN transistor. The plot 200 shows the Alpha ratio reduced by approximately three orders of magnitude by adding DTI, meaning the leakage currents are reduced by a factor of around 1,000. Even with such a large Alpha ratio reduction, however, there remains significant leakage, particularly as the spacing between devices is reduced.

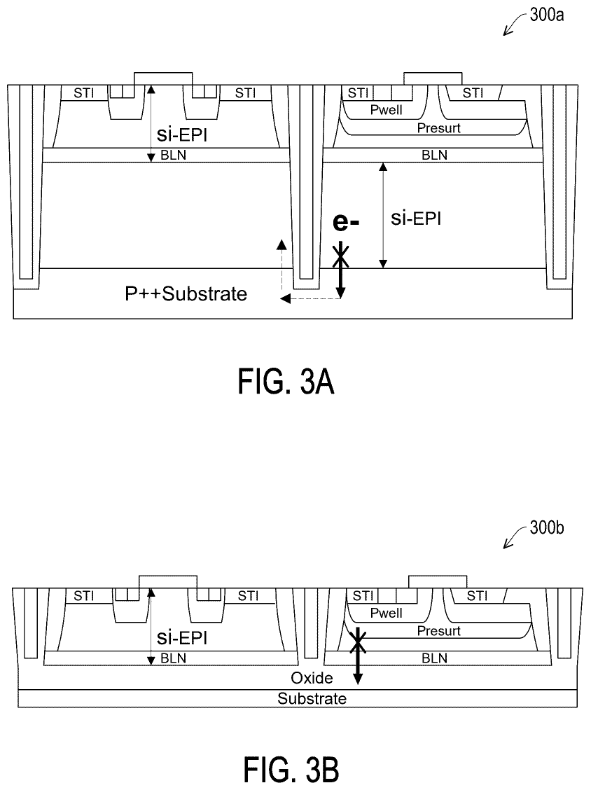

FIGS. 3A and 3B show an example of a lateral DMOS transistor 300a with both DTI and a P+ substrate, and a lateral DMOS transistor 300b with DTI and SOI technology, respectively. The illustrated structure of FIG. 3A demonstrates that the P+ substrate can help to reduce electron injection, thereby enhancing isolation for example by reducing electron leakage. Similarly, the illustrated structure of FIG. 3B demonstrates that SOI technology can provide superior isolation by reducing vertical leakage paths. However, as noted above, both such approaches tend to have appreciable cost implications.

Embodiments described herein incorporate one or more silicon-boron (Si:B) epitaxially grown (EPI) buried layers into HV-BCD device structures to achieve robust transistor isolation. Some embodiments further include layers co-doped with one or more of oxygen (O), carbon (C), and/or other materials, to help limit diffusion growth, thereby controlling thickness of a P-EPI layer. For example, the additional co-doped layer(s) help to control and/or improve thickness, dopant profile, breakdown voltage (Vbd), and/or other features of the P-EPI layer. The strong interaction between silicon self-interstitials and co-dopants can enhance boron blocking and electron leakage properties.

As described herein, such novel structures can reduce the parasitic NPN transistor effect by controlling the alpha ratio, which is highly correlated with the boron concentration in the Si:B layer and the electron diffusion barrier. For example, with such approaches, the boron diffusion length can be approximately 5.5 microns (μm) at a boron concentration of 5E18 atoms/cm³ after front-end-of-line (FEOL) thermal processing. Further incorporating substitutional carbon during annealing can suppress transient enhanced diffusion (TED) of boron, and epitaxially grown carbon-rich layers can help prevent boron upward diffusion and vertical current leakage, thus enhancing isolation performance. Further, incorporation of an oxygen-doped layer (in addition to, or instead of the carbon co-doping) can appreciably reduce vertical leakage and boron diffusion. Embodiments described herein can include only the P+ EPI layer(s), the P+ EPI layer(s) with co-doped carbon, the P+ EPI layer(s) with co-doped oxygen, the P+ EPI layer(s) with co-doped carbon and oxygen, and/or other embodiments. As described herein, the co-doping can be achieved by using Low-Pressure Chemical Vapor Deposition (LPCVD) to produce in-situ Si:B EPI co-doped with carbon and oxygen. Other implementations can include implanting various dopants (e.g., carbon, oxygen, nitrogen, fluorine, boron, etc.).

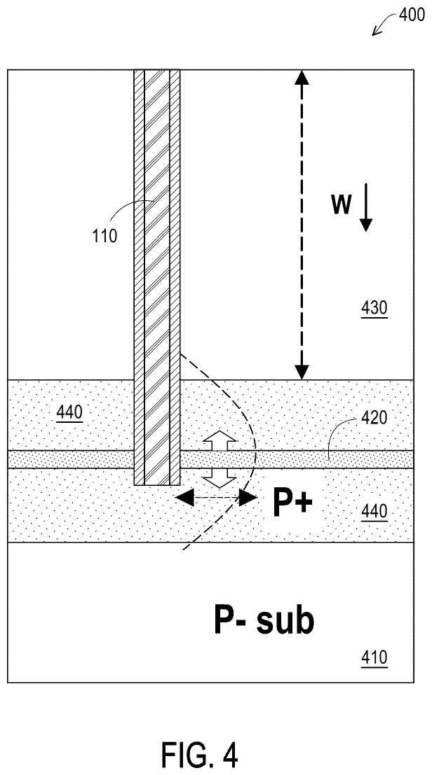

FIG. 4 shows an illustrated HV-BCD device structure 400 including a buried P+ EPI layer 420, according to some embodiments described herein. As illustrated, the device structure 400 includes a P+ EPI layer 420 sandwiched between (i.e., buried between) a P− substrate layer 410 and a P− EPI layer 430. A P+ diffusion region 440 is shown around (extending above and below) the P+ EPI layer 420. A DTI structure 110 is also shown penetrating through the P− EPI layer 430 and the P+ EPI layer 420 (including at least partially through the P+ diffusion region 440). As described herein, performance of the HV-BCD device can be appreciably impacted by the width (W) of the P− EPI layer 430.

The P− substrate layer 410 forms the foundational base of the HV-BCD device structure 400. It is composed of lightly doped p-type silicon. For example, the doping concentration can be in the range of 10¹⁴-10¹⁶ atoms/cm³. This layer provides the mechanical support for the entire device and serves as the primary substrate upon which the subsequent epitaxial layers are grown. The P− substrate layer 410 can be formed through standard silicon wafer fabrication processes, such as doping the silicon wafer with p-type dopants, such as boron, during the crystal growth phase. Functions of the P− substrate layer 410 include to act as a low-resistance path for current flow, to ensure the structural integrity of the device, and to affect the distribution of electric fields within the structure.

The P− EPI layer 430 is a lightly doped p-type epitaxial layer. This layer can have a doping concentration similar to that of the P− substrate layer 410, such as in the range of 10¹⁴-10¹⁶ atoms/cm³. The thickness can vary depending on specific design requirements. Some embodiments described herein assume a desired thickness (or width, W) of around 27 microns. The P− EPI layer 430 is formed using epitaxial growth techniques. Generally, the P− EPI layer 430 functions as the active region for the formation of various device components, such as transistors and diodes. Properties of the P− EPI layer 430 can have an appreciable impact on electrical characteristics of the device, such as breakdown voltage (Vbd) and on-resistance (R_on).

The DTI structure 110 consists of deep trenches etched into the silicon substrate and filled with an insulating material such as silicon dioxide (SiO₂). The trenches are typically created using advanced lithography and etching techniques, followed by the deposition of the insulating material. As described above, the DTI structure 110 can help to provide electrical isolation between different regions of the device, such as to mitigate formation of parasitic NPN transistors that can lead to leakage currents. By creating a physical barrier, the DTI structure 110 can help confine electric fields to within desired regions, thereby enhancing the device's reliability and performance, particularly under high-voltage conditions.

In some conventional devices, there is no P− substrate layer 410. Instead, a P+ substrate layer is formed on top of a low-temperature oxide (LTO) layer. The P− EPI layer 430 can be formed on the P+ substrate layer, and the DTI structure 110 can penetrate through the P− EPI layer 430 and into the P+ substrate layer. Such a conventional structure can achieve reduced Alpha ratio (e.g., 10⁻³) but can be relatively expensive to implement.

In the illustrated HV-BCD device structure 400, as noted above, the P− substrate layer 410 is used as the base substrate without an LTO layer. The P+ EPI layer 420 (Si:B layer) is grown on the P− substrate layer 410, and the P− EPI layer 430 is grown on the P+ EPI layer 420, so that the P− EPI layer 430 is effectively buried below the P− EPI layer 430 and sandwiched between the P− substrate layer 410 and the P− EPI layer 430. The P+ EPI layer 420 is a heavily doped p-type epitaxial layer, for example, having a doping concentration in the range of approximately 10¹⁸-10²⁰ atoms/cm³. In some implementations, the P+ EPI layer 420 can have a thickness ranging between approximately 200 nanometers to 10 microns. In some such implementations, the P+ EPI layer 420 has a thickness of approximately 0.1 to 1 micron.

The P+ EPI layer 420 is formed using epitaxial growth techniques, where a silicon wafer is exposed to a high-purity silicon source gas, often in combination with a p-type dopant source, under high-temperature conditions in a chemical vapor deposition (CVD) reactor. The epitaxial growth of the P+ EPI layer 420 can be similar to those used for growing the P− EPI layer 430, except that the P− EPI layer 430 tends to be grown with lower dopant concentration. As described herein, the P+ EPI layer 420 functions as a barrier to prevent the diffusion of boron from the P− substrate layer 410 into the upper layers of the device (including the P− EPI layer 430). This barrier helps to maintain the integrity of the doping profiles and to ensure the proper functioning of the HV-BCD device. Additionally, the P+ EPI layer 420 helps to reduce vertical leakage currents and enhance the overall isolation performance of the device by blocking unwanted current paths.

As illustrated, a P+ diffusion region 440 surrounds the P+ EPI layer 420, extending both above and below it. This region is created through a diffusion process, where p-type dopants, such as boron, are introduced into the silicon substrate at high temperatures, allowing the dopants to diffuse into the desired regions. The doping concentration in the P+ diffusion region is typically in the range of approximately 10¹⁸-10²⁰ atoms/cm³. The P+ diffusion region 440 functions to provide additional isolation by enhancing the boron blocking properties of the P+ EPI layer 420. This region helps to prevent the vertical and lateral diffusion of boron, thereby maintaining the integrity of the doping profiles and reducing leakage currents. Additionally, the P+ diffusion region contributes to the overall robustness of the device by enhancing the effectiveness of the DTI structures 110 and improving the isolation between different regions of the HV-BCD device structure 400.

Manufacturing of such a HV-BCD device structure 400 can involve one or more epitaxial growth stages, in which at least the P+ EPI layer 420 and the P− EPI layer 430 are grown on the P− substrate layer 410. For example, chemical vapor deposition (CVD) techniques are used to deposit high-purity silicon layers with controlled doping concentrations. Subsequent to epitaxial growth of at least the P+ EPI layer 420 and the P− EPI layer 430, the manufacturing process can include at least one diffusion stage, in which the P+ diffusion region 440 is formed through a high-temperature diffusion process. In this stage, p-type dopants, such as boron, are introduced into the silicon substrate. The diffusion process involves heating the substrate to a high temperature (e.g., around 900-1100 degrees Celsius), allowing the boron atoms to diffuse into the silicon and create a heavily doped P+ region.

The high-temperature diffusion process tends to reduce the width (W) of the P− EPI layer 430 due to the thermal diffusion of dopants, which can alter the dopant profiles and consequently the electrical properties of the epitaxial layers. In particular, during high-temperature diffusion, dopants can tend to diffuse into adjacent regions, including into the P− EPI layer 430. This redistribution of dopants changes the concentration profiles within the epitaxial layers, resulting in an encroachment of the P+ diffusion region 440 into the P− EPI layer 430, effectively reducing W.

At very high temperatures used for diffusion, dopant atoms gain sufficient energy to move through the silicon lattice, driven by concentration gradients. Boron atoms diffuse from regions of high concentration (P+ diffusion region 440) to regions of lower concentration (P− EPI layer 430), causing the boundary of the P+ diffusion region 440 to move outward and reducing the effective width of the P− EPI layer 430 by a reduction amount (R). The value of R (i.e., the extent of the reduction in W) depends on the diffusion temperature and duration, as well as the initial dopant concentrations. In some embodiments, it is expected that the high-temperature diffusion process will reduce W by approximately two microns (i.e., R≈2 μm). Some embodiments grow the P− EPI layer 430 with an initial width (W₀) that results in a final width (W_{f}) that accounts for the anticipated reduction due to diffusion (i.e., W₀=W_{f}+R).

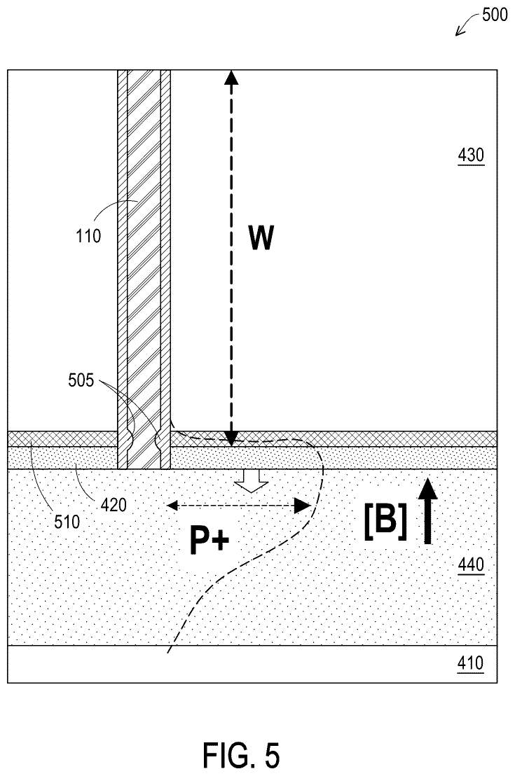

FIG. 5 shows an illustrated HV-BCD device structure 500 that is similar to the HV-BCD device structure 400 of FIG. 4 with additional one or more co-doped layers 510, according to some embodiments described herein. Similar to the HV-BCD device structure 400 of FIG. 4, the HV-BCD device structure 500 of FIG. 5 includes a P+ EPI layer 420 sandwiched between a P− substrate layer 410 and a P− EPI layer 430, with a DTI structure 110 penetrating through the P− EPI layer 430 and the P+ EPI layer 420. In the HV-BCD device structure 500 of FIG. 5, the P+ EPI layer 420 is implemented as multiple layers (i.e., at least two layers) including at least one co-doped layer 510. As described herein, the co-doped layer(s) 510 prevent the P+ diffusion region 440 from encroaching upward into the P− EPI layer 430. As illustrated, the P+ diffusion region 440 extends primarily (or only) below the P+ EPI layer 420.

As noted above, the co-doped layer(s) 510 are strategically incorporated to ensure that the P+ diffusion region 440 extends only away from the P− EPI layer 430, thereby enhancing the overall isolation and performance of the device. The co-doped layer(s) 510 are composed of silicon (Si) that is co-doped with one or more elements, such as oxygen (O), carbon (C), and/or boron (B). The co-doped layer(s) 510 can be formed using epitaxial growth techniques, similar to those used for the P+ EPI layer 420 and the P− EPI layer 430, but with the introduction of additional dopant sources during the chemical vapor deposition (CVD) process. In this way, co-dopants are introduced into the silicon lattice to achieve the desired concentration and distribution. In one implementation, an oxygen-doped layer has oxygen concentration in the range of 10²⁰-10²¹ atoms/cm³. In another implementation, a carbon-doped layer has a carbon concentration in the range of 10¹⁹-10²⁰ atoms/cm³. These concentrations are carefully controlled to optimize the electrical and diffusion properties of the co-doped layers. In some implementations, the width of such co-doped layer(s) 510 is in the range of approximately 10-100 nanometers.

The co-doped layer(s) 510 are positioned adjacent to or within the P+ EPI layer 420. In embodiments including the co-doped layer(s) 510, the co-doped layer(s) 510 can be considered as layers of a multi-layer P+ EPI layer 420 (i.e., reference to the P+ EPI layer 420 can include only a P+ EPI layer 420 in some embodiments, or a P+ EPI layer 420 and one or more co-doped layer(s) 510 in other embodiments). The co-doped layer(s) 510 interact with the P+ EPI layer 420 to modulate the diffusion characteristics and to enhance isolation. The co-dopants are selected to have a strong interaction with silicon self-interstitials, which are defects in the silicon lattice that can facilitate dopant diffusion. By incorporating these co-dopants, the diffusion of boron atoms from the P+ EPI layer 420 can be effectively suppressed, preventing the unwanted encroachment of the P+ diffusion region 440 into the P− EPI layer 430.

In some such embodiments, the thermal diffusion process is performed for several (e.g., four) hours at a high temperature (e.g., 1100° C.). During that process, the P+ diffusion region 440 can grow to approximately 3-10 microns as the boron concentration exceed a desired threshold of 1E18 atoms/cm³.

In the illustrated HV-BCD device structure 500, the co-doped layer(s) 510 provide several features. One feature is that the co-doped layer(s) 510 act as barriers to boron diffusion, ensuring that the P+ diffusion region 440 extends only away from the P− EPI layer 430. This controlled diffusion helps maintain the integrity of the P− EPI layer 430, preserving its width (W) and preventing the degradation of its electrical properties. A second feature is that, by limiting boron diffusion, the co-doped layer(s) 510 enhance the isolation between different regions of the device, which helps reduce leakage currents and prevent the formation of parasitic NPN transistors that can degrade device performance. A third feature is that the presence of oxygen and/or carbon in the co-doped layer(s) 510 helps to improve the breakdown voltage (Vbd) of the device. Such elements create traps for charge carriers, reducing the likelihood of premature breakdown and enhancing the device's ability to operate reliably at high voltages. A fourth feature is that some such co-dopants (e.g., carbon) are particularly effective in suppressing transient enhanced diffusion (TED) of boron during thermal processing. This suppression is achieved by the formation of carbon-silicon bonds, which immobilize silicon self-interstitials and prevent them from facilitating boron diffusion. As a result, the boron diffusion length is reduced, further enhancing the isolation and performance of the device. A fifth feature is that inclusion of one or more oxygen-doped layers (e.g., in addition to or instead of carbon co-doping) can appreciably reduce vertical leakage currents. For example, a high concentration of oxygen can create deep-level traps in the silicon lattice, capturing free electrons and holes and thereby reducing leakage currents.

The HV-BCD device structures described in FIGS. 4 and 5 provide certain features over conventional structures. For example, the novel structures described herein, with the P− substrate layer 410 and the buried P+ EPI layer 420, tend to be appreciably less expensive than the P+ substrate-based structures of conventional approaches. Additionally, novel structures described herein yields an appreciably reduced Alpha ratio as compared to the Alpha ratio resulting from a structure built with a P+ substrate on a LTO layer. For example, the HV-BCD device structure 400 of FIG. 4 manifests an Alpha ratio around 10⁻⁶, which is around 3 orders of magnitude lower than conventional approaches. Further, the HV-BCD device structure 500 of FIG. 5 provides additional features, such as improved control over W, dopant concentrations, V_bd, etc.

The HV-BCD device structure 500 of FIG. 5 shows a small hump 505 formed in the DTI structure 110. The hump 505 may be on the order of 0.1-1.5 percent of the diameter of the DTI structure 110. For example, the DTI structure 110 is approximately 2.5 microns in diameter, and the hump 505 protrudes approximately 5-30 nm (i.e., 0.2-1.2 percent) into the DTI structure 110. The hump 505 can result (e.g., unintentionally) from interactions between the DTI structure 110 formation and the P+ EPI layer 420 and/or the co-doped layer(s) 510. For example, the P+ EPI layer 420 and/or co-doped layer(s) 510 can influence the etching and filling process for the DTI structure 110 due to differences in etch rates, material properties, and stress distribution. The co-doped layer(s) 510, in particular, may have different physical and chemical properties compared to the undoped silicon or standard epitaxial silicon layers, which can cause variations in the trench profile during the etching process and affect the uniformity of the insulating material deposition, resulting in the hump 505. Similarly, the introduction of co-dopants, like oxygen and carbon, into the silicon lattice can create localized stress due to lattice mismatch, which can cause slight deformations or irregularities in the DTI structure 110 trench walls and bottom during the etching process, resulting in a small hump 505. The high-temperature diffusion processes can cause dopant redistribution and/or stress relaxation, further contributing to the formation of the hump 505.

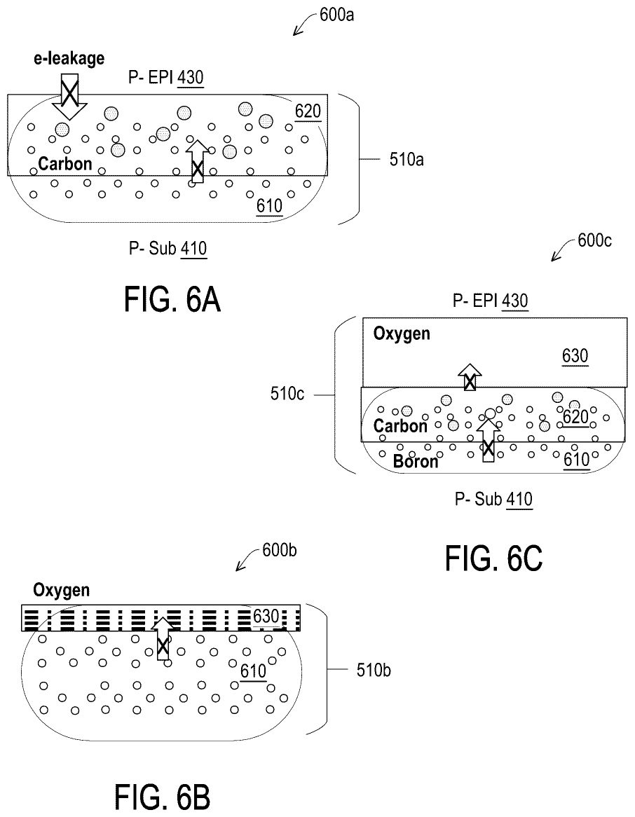

FIG. 6A-6C show three illustrative partial structures 600 representing examples of co-doped layer(s) 510 of the P+ EPI layer 420, according to some embodiments described herein. In FIG. 6A, the structure 600a shows a first example implementation of co-doped layer(s) 510a sandwiched between a P− substrate layer 410 and a P− EPI layer 430. A boron (B) co-doped region 610 and a carbon (C) co-doped region 620 form C/B co-doped layer(s) 510a of a P+ EPI layer 420. The carbon co-doped region 620 is formed through an epitaxial growth process using chemical vapor deposition (CVD) where a high-purity silicon source gas is combined with boron and carbon dopant sources at high temperatures to achieve the desired doping concentrations. The carbon atoms in the carbon co-doped region 620 interact strongly with silicon self-interstitials, effectively immobilizing them and preventing boron diffusion. This carbon co-doped region 620 acts as a robust barrier to boron diffusion, ensuring boron atoms remain confined within the P+ region and do not encroach into the adjacent P− EPI layer. Additionally, the carbon in the carbon co-doped region 620 reduces electron leakage by creating deep-level traps in the silicon lattice, which capture free electrons and prevent them from contributing to leakage currents. This dual function of the P+ EPI layer 420 with the carbon co-doped region 620 enhances the isolation performance of the HV-BCD device.

In one implementation, the structure 600a includes three layers (or sets of layers) built on top of the P− substrate layer 410. The first layer is a Si:B region of the P+ EPI layer 420 having a thickness of around 0.1-1 microns. The second layer is one or more C/B co-doped layer(s) 510a of the P+ EPI layer 420 having a thickness of around 10-20 nanometers and a carbon concentration of around 5E19-5E20 atoms/cm³. Alternatively, the one or more C/B co-doped layer(s) 510a of the P+ EPI layer 420 have a thickness of around 50-1000 nanometers The third layer is the P− EPI layer 430 having a thickness of around 27 microns.

In FIG. 6B, the structure 600b shows a second example implementation of co-doped layer(s) 510b sandwiched between a P− substrate layer 410 and a P− EPI layer 430. A boron (B) co-doped region 610 and an oxygen (O) co-doped region 630 form O/B co-doped layer(s) 510b of a P+ EPI layer 420. The oxygen co-doped region 630 is formed through an epitaxial growth process using low-pressure chemical vapor deposition (LPCVD), where a silicon source gas is combined with boron and oxygen dopant sources, resulting in a co-doped region with a high oxygen concentration (e.g., in the range of 10²⁰-10²¹) atoms/cm³. The oxygen atoms interact with silicon self-interstitials, forming stable silicon-oxygen bonds that create deep-level traps in the silicon lattice. These traps capture free electrons, significantly reducing vertical leakage currents. The oxygen-doped P+ EPI layer also acts as an effective barrier to boron diffusion, preventing the upward diffusion of boron atoms into the P− EPI layer 430. This controlled diffusion maintains the integrity of the P− EPI layer 430, preserving its width (W) and ensuring optimal electrical properties. Thus, the oxygen co-doped region 630 acts to prevent electron leakage from the P− EPI layer 430 and to prevent boron diffusion from the boron co-doped region 610.

In one implementation, the structure 600b includes three layers (or sets of layers) built on top of the P− substrate layer 410. The first layer is a Si:B region of the P+ EPI layer 420 having a thickness of around 0.1-1 microns. The second layer is one or more O/B co-doped layer(s) 510 b of the P+ EPI layer 420 having a thickness of around 10-30 nanometers and an oxygen concentration of around 1E20-1E21 atoms/cm³. The third layer is the P− EPI layer 430 having a thickness of around 27 microns. Alternatively, the second layer is one or more O/B co-doped layer(s) 510b of the P+ EPI layer 420 having a thickness of around 15 nanometers, and the third layer is the P− EPI layer 430 having a thickness of around 6 microns.

In one implementation, the oxygen co-doped region 630 is implemented as multiple layers. A first layer above the P− substrate layer 410 is a buffer layer (e.g., having a thickness around 18.75 Angstroms). The buffer layer can manage stress and defects that may arise from lattice mismatches between the substrate and the subsequent epitaxial layers. Above the buffer layer are alternating oxygen co-doped layers and spacer layers. For example, 8 layers can be formed as (1) oxygen co-doped layer, (2) spacer layer, (3) oxygen co-doped layer, (4) spacer layer, (5) oxygen co-doped layer, (6) spacer layer, (7) oxygen co-doped layer, and (8) spacer layer. As noted above, the oxygen-doped layers form stable silicon-oxygen bonds that create deep-level traps in the silicon lattice to effectively capture free electrons, reduce vertical leakage currents, and act as barriers to boron diffusion. The spacer layers are undoped or lightly doped silicon that help to provide structural integrity and to maintain the desired separation between the oxygen-doped layers, thereby ensuring that an overall dopant profile is maintained. Above the alternating layers, there can be a silicon capping layer, which can provide a smooth and defect-free surface for subsequent device processing steps and protects the underlying layers from contamination and mechanical damage. Together, the layers can have a thickness of around 15 nanometers.

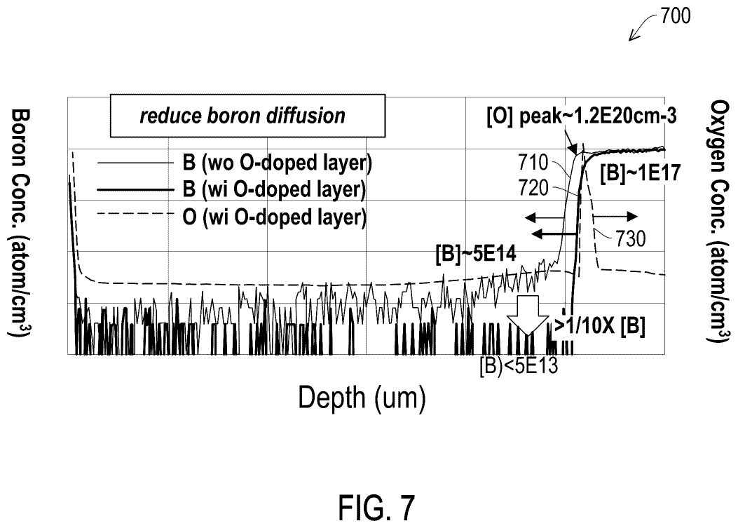

Turning briefly to FIG. 7, a secondary ion mass spectrometry (SIMS) profile plot 700 demonstrates that an oxygen-doped layer reduces boron diffusion. In particular, the plot 700 includes a first curve 710 representing boron concentrations at different depths without an oxygen-doped layer, a second curve 720 representing boron concentrations at different depths with an oxygen-doped layer, and a third curve 730 representing oxygen concentrations at different depths with an oxygen-doped layer.

The peak of the third curve 730 coincides with the depth of the oxygen-doped layer, which is at around 5.14 microns (where there is an oxygen concentration of around 1.2E20 atoms/cm³). The first curve 710 shows that, without an oxygen-doped layer, there is a high boron concentration at depths as shallow as around 5 microns. In contrast, the second curve 720 shows that, with an oxygen-doped layer, the boron concentration drops off effectively at the depth of the oxygen-doped layer. Further, the boron concentration drops more dramatically in presence of the oxygen-doped layer. For example, comparing the first curve 710 and the second curve 720 at depths of less than around 5 microns, the boron concentration with the oxygen-doped layer is at least an order of magnitude below the boron concentration without the oxygen-doped layer.

Turning back to FIG. 6C, the structure 600c shows a third example implementation of co-doped layer(s) 510c sandwiched between a P− substrate layer 410 and a P− EPI layer 430. A boron (B) co-doped region 610, a carbon (C) co-doped region 620, and an oxygen co-doped region 630 form C/O/B co-doped layer(s) 510c of a P+ EPI layer 420. The carbon co-doped region 620 and the oxygen co-doped region 630 are formed sequentially through epitaxial growth processes using low-pressure chemical vapor deposition (LPCVD). During the LPCVD process, a silicon source gas is combined with boron, carbon, and oxygen dopant sources in different stages to create distinct co-doped layers within the P+ EPI region 420. Embodiments position the carbon co-doped region 620 closer to the P− substrate layer 410, such that the carbon interacts with silicon self-interstitials to suppress transient enhanced diffusion (TED) of boron and reduce electron leakage. The oxygen co-doped region 630 can be positioned above the carbon co-doped region 620, creates deep-level traps that further reduce vertical leakage currents and enhance the boron blocking properties. This multi-layered co-doping approach ensures that the P+ diffusion region 440 extends only away from the P− EPI layer 430, maintaining the integrity of the P− EPI layer 430 and preserving its width (W). The combined effect of the carbon co-doped region 620 and oxygen co-doped region 630 results in a highly effective barrier to both boron diffusion and electron leakage, improving the isolation performance of the HV-BCD device.

In the above example structures, the P− EPI layer 430 is generally described and illustrated as a cohesive layer. In some implementations, the P− EPI layer 430 includes an N+ buried layer (NBL). For example, a first portion of the P− EPI layer 430 (EPI_0) is grown on top of the P+ EPI layer 420 (e.g., on top of the co-doped layer(s) 510), the N+ buried layer (NBL) is disposed on top of EPI_0, and a second portion of the P− EPI layer 430 (EPI_1) is grown on top of the NBL. In one such embodiment, EPI_0 is less than or equal to approximately 12 nanometers wide, and EPI_1 is less than or equal to approximately 15 nanometers wide, so that EPI_0, the NBL, and EPI_1 together are approximately 27 nanometers wide.

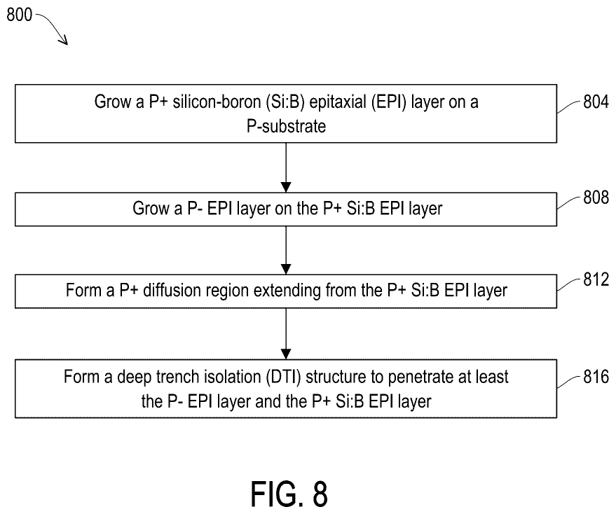

FIG. 8 shows a flow diagram of a method 800 for producing electrical isolation between high-voltage bipolar-CMOS-DMOS (HV-BCD) devices, according to embodiments described herein. Embodiments begin at stage 804 by growing a P+ silicon-boron (Si:B) epitaxial (EPI) layer on a P− substrate. For example, the P− substrate can be formed by selecting a high-quality silicon wafer and lightly doping it with p-type dopants, such as boron, to achieve a doping concentration in the range of 10¹⁴-10¹⁶ atoms/cm³. The substrate can then be cleaned and polished to ensure a defect-free surface, providing a robust foundation for subsequent epitaxial growth.

The epitaxial growth of the P+ EPI layer in stage 804 can involve using a chemical vapor deposition (CVD) process, including combining a silicon source gas with a high-concentration of boron dopant to form a heavily doped p-type epitaxial layer. The doping concentration for the P+ EPI layer can be in the range of 10¹⁸-10²⁰ atoms/cm³. As described herein, in some embodiments, the P+ Si:B EPI layer is a buried P+ EPI layer or layers having a width of approximately 200 nanometers to 10 microns.

In some embodiments, growing the P+ Si:B EPI layer at stage 804 involves forming one or more co-doped layers by introducing one or more dopants into the epitaxial growth process for the P+ Si:B EPI layer. For example, the resulting P+ Si:B EPI layer is the buried P+ EPI layer(s) with the co-doped layer(s) on top (e.g., formed sequentially). In some implementations, the co-doped layers are formed through low-pressure chemical vapor deposition (LPCVD), where a silicon source gas is combined with boron, oxygen, and/or carbon dopant sources in controlled stages. As described herein, the one or more co-doped layers of the P+ Si:B EPI layer can include one or more carbon-boron (C/B) co-doped layers and/or one or more oxygen-boron (O/B) co-doped layers. For example, the one or more oxygen-boron (O/B) co-doped layers can be implemented as a stack of layers alternating between oxygen-doped layers and spacer layers.

At stage 808, embodiments can grow a P− EPI layer on the P+ Si:B EPI layer. The P− EPI layer can be grown on top of the P+ EPI layer using the same CVD process as for the P+ Si:B EPI layer, but with a lower boron concentration (e.g., achieving a doping range of 10¹⁴-10¹⁶ atoms/cm³).

At stage 812, embodiments can form a P+ diffusion region extending from the P+ Si:B EPI layer (e.g., extending below and/or above). For example, a high-temperature boron diffusion process is performed at a temperature of at least 900 degrees Celsius (e.g., at 1100 degrees Celsius) for at least three hours (e.g., for four hours). In some embodiments, the P− EPI layer has a target final width (Wf). In such embodiments, forming the P+ diffusion region at stage 812 causes the P+ diffusion region to encroach into the P− EPI layer by a reduction amount (R); and growing the P− EPI layer at stage 808 comprises growing the growing a P− EPI layer to an initial width (Wi) corresponding to Wf+R, so that the width of the P− EPI layer is Wf after forming the P+ diffusion region. For example, desired electrical properties are achieved when the P− EPI layer is 27 microns, and the diffusion process causes the P+ diffusion region to encroach into the P− EPI layer by 2 microns; so the P− EPI layer is grown at stage 808 to an initial width (Wi) of 29 microns, corresponding to 27 microns (the Wf in this example) plus 2 microns (the R in this example).

At stage 816, embodiments can form a deep trench isolation (DTI) structure in a region between the two HV-BCD devices to penetrate at least the P− EPI layer and the P+ Si:B EPI layer. The DTI structures are formed by etching deep trenches into the silicon substrate, penetrating through at least the P− EPI layer and the P+ Si:B EPI layer. The trenches are then filled with an insulating material, such as silicon dioxide, using techniques like CVD or PECVD.

The foregoing merely outlines features of embodiments of the disclosure. Various modifications and alterations to the described embodiments will be apparent to those skilled in the art in view of the teachings herein. Those skilled in the art will appreciate that equivalent constructions do not depart from the scope of the present disclosure, and that they may make various changes, substitutions, and alterations herein without departing from the spirit and scope of the present disclosure.

What is claimed is:

1. A method for producing electrical isolation between high-voltage bipolar-CMOS-DMOS (HV-BCD) devices, the method comprising:
growing a P+ silicon-boron (Si:B) epitaxial (EPI) layer on a P− substrate of a semiconductor device having a plurality of HV-BCD devices;
growing a P− EPI layer on the P+ Si:B EPI layer;
forming a P+ diffusion region extending from the P+ Si:B EPI layer; and
forming a deep trench isolation (DTI) structure in a region between adjacent ones of the HV-BCD devices to penetrate at least the P− EPI layer and the P+ Si:B EPI layer.

2. The method of claim 1, wherein:
the P− EPI layer has a target final width (Wf);
forming the P+ diffusion region causes the P+ diffusion region to encroach into the P− EPI layer by a reduction amount (R); and
growing the P− EPI layer comprises growing the growing a P− EPI layer to an initial width (Wi) corresponding to Wf+R, so that the width of the P− EPI layer is Wf after forming the P+ diffusion region.

3. The method of claim 1, wherein the growing the P+ Si:B EPI layer comprises forming one or more co-doped layers of the P+ Si:B EPI layer by introducing one or more dopants into an epitaxial growth process.

4. The method of claim 3, wherein the one or more co-doped layers of the P+ Si:B EPI layer comprises one or more carbon-boron (C/B) co-doped layers.

5. The method of claim 3, wherein the one or more co-doped layers of the P+ Si:B EPI layer comprises one or more oxygen-boron (O/B) co-doped layers.

6. The method of claim 5, wherein the one or more oxygen-boron (O/B) co-doped layers comprises a stack of layers alternating between oxygen-doped layers and spacer layers.

7. The method of claim 5, wherein the one or more co-doped layers of the P+ Si:B EPI layer further comprises one or more carbon-boron (C/B) co-doped layers.

8. The method of claim 1, wherein the forming the P+ diffusion region comprises diffusing boron at a temperature of at least 900 degrees Celsius for at least three hours.

9. A semiconductor device comprising:
a P− substrate;
a P+ silicon-boron (Si:B) epitaxial (EPI) layer grown on the P− substrate;
a P− EPI layer grown on the P+ Si:B EPI layer;
a P+ diffusion region extending from the P+ Si:B EPI layer; and
a deep trench isolation (DTI) structure penetrating at least the P− EPI layer and the P+ Si:B EPI layer.

10. The semiconductor device of claim 9, wherein the P+ Si:B EPI layer has a width in the range of 200 nanometers to 10 microns.

11. The semiconductor device of claim 9, wherein the P+ Si:B EPI layer comprises one or more co-doped layers.

12. The semiconductor device of claim 11, wherein the one or more co-doped layers of the P+ Si:B EPI layer comprises one or more carbon-boron (C/B) co-doped layers.

13. The semiconductor device of claim 12, wherein:
the one or more C/B co-doped layers are formed on top of a buried P+ layer (BPL) of the P+ Si:B EPI layer;
the BPL has a width in the range of 200 nanometers to 10 microns; and
the one or more C/B co-doped layers has a combined width in the range of 50 to 100 nanometers.

14. The semiconductor device of claim 12, wherein the one or more C/B co-doped layers has a carbon concentration on the order of 5E19 to 5E20 atoms/cm³.

15. The semiconductor device of claim 11, wherein the one or more co-doped layers of the P+ Si:B EPI layer comprises one or more oxygen-boron (O/B) co-doped layers.

16. The semiconductor device of claim 15, wherein:
the one or more O/B co-doped layers are formed on top of a buried P+ EPI layer of the P+ Si:B EPI layer;
the buried P+ EPI layer has a width in the range of 200 nanometers to 10 microns; and
the one or more O/B co-doped layers has a combined width in the range of 10 to 30 nanometers.

17. The semiconductor device of claim 15, wherein the one or more O/B co-doped layers has an oxygen concentration on the order of 10²⁰ to 10²¹ atoms/cm³.

18. The semiconductor device of claim 15, wherein the one or more oxygen-boron (O/B) co-doped layers comprises a stack of layers alternating between oxygen-doped layers and spacer layers.

19. The semiconductor device of claim 15, wherein the one or more co-doped layers of the P+ Si:B EPI layer further comprises one or more carbon-boron (C/B) co-doped layers.

20. A semiconductor device comprising:
a P− substrate;
a P+ silicon-boron (Si:B) epitaxial (EPI) layer grown on the P− substrate;
a P− EPI layer grown on the P+ Si:B EPI layer;
a P+ diffusion region extending from the P+ Si:B EPI layer;
a plurality of high-voltage bipolar-CMOS-DMOS (HV-BCD) devices formed on the P− EPI layer; and
a plurality of deep trench isolation (DTI) structures penetrating at least the P− EPI layer and the P+ Si:B EPI layer, wherein each DTI structure is disposed between adjacent ones of the plurality of HV-BCD devices.
